(19) United States
(12) Patent Application Publication
(10) Pub. No.: US 2019/0008075 A1
(43) Pub. Date: Jan. 3, 2019

(54) ARC SHAPE FRONT PANEL

(71) Applicant: QUANTA COMPUTER INC., Taoyuan City (TW)

(72) Inventors: Chao-Jung CHEN, Taoyuan City (TW); Yu-Nien HUANG, Taoyuan City (TW); Herman TAN, Taoyuan City (TW)

(21) Appl. No.: 15/895,363

(22) Filed: Feb. 13, 2018

Related U.S. Application Data
(60) Provisional application No. 62/527,273, filed on Jun. 30, 2017.

(51) Int. Cl. H05K 7/20; H05K 7/14

(52) U.S. Cl. CPC H05K 7/20709; H05K 7/1452

(57) ABSTRACT

A faceplate of an apparatus is provided. The faceplate includes a top panel and a front panel. The top panel includes a portion angled towards a front side of the faceplate. The angled portion includes an obtuse angle. The front panel disposed on the front side of the faceplate includes a first face and a second face angled towards the front side of the faceplate. The first face and the second face both include a plurality of holes. The angled portion of the top panel, the angled first face, and the angled second face facilitate an intake/outlet area for air flow across the front side of the front side of the face plate into the plurality of holes.

### CROSS REFERENCE TO RELATED APPLICATIONS

This application claims priority to U.S. Provisional Application No. 62/527,273 entitled “ARC SHAPE FRONT PANEL”, filed on Jun. 30, 2017, the contents of which are incorporated by reference.

### FIELD OF THE INVENTION

The present invention relates to apparatuses for dissipating heat that emanates from individual electronic units housed within a server device.

### BACKGROUND

Most modern communications equipment includes heat generating electronic components that have to be cooled to enable them to function effectively. Typically, the electronic components are cooled using air that is forced into the equipment chassis to flow over the electronic components. In data center environments with large number of electronic components, thermal management can be a challenge. Some data centers utilize a hot aisle/cold aisle layout design for server racks and other computing equipment, to conserve energy and lower cooling costs by managing air flow effectively.

In its simplest form, hot aisle/cold aisle data center design involves lining up server racks in alternating rows with cold air intakes facing one direction, and hot air exhausts facing the opposite direction. The rows composed of rack fronts are called cold aisles. Typically, cold aisles face air conditioner output ducts. The rows, into which heated exhausts pour, are called hot aisles. Typically, hot aisles face air conditioner return ducts. Cool air thus enters at the front, and hot air exits at the back.

Equipment used in such hot aisle/cold aisle data centers may have front-to-back airflow cooling. For example, in a switch comprising a plurality of line cards, the air enters at a front panel faceplate of each individual line card (e.g., front panel being perpendicular to the length of the line card), passes through a mid-plane of the line card, and exits at the back of the switch chassis. The front panel can include vents, which permit air to enter the chassis. The perforation area can affect board-level (e.g., at the line card level) and system-level (e.g., at the switch chassis level) cooling. However, port density of the line-cards is already quite high, and expected to increase in the future. The increasing number of ports on the faceplate in consideration of the limited total exposed area of the faceplate, presents a challenge in configuring the perforations on the front panel faceplate. Moreover, the power dissipation and cooling demands are increased proportional to the port density. However, with the increased port density, the perforation area is reduced. Thus, the cooling capacity of the line card is reduced.

The inability to remove this heat can result in accelerated aging and/or premature failure of the interconnection of other components. Therefore, there is a need to provide a cooling system in high speed communication devices that facilitates high-heat removal and dense packaging of the interconnections.

### SUMMARY

Embodiments of the invention concern a faceplate for cooling an electronic apparatus, and all of the electrical components installed within that electronic apparatus. The faceplate includes a top panel and a front panel. The top panel includes a portion angled towards a front side of the faceplate. The angled portion includes an obtuse angle. The front panel disposed on the front side of the faceplate includes a first face and a second face angled towards the front side of the faceplate. The first face and the second face both include a plurality of holes. The angled portion of the top panel, the angled first face, and the angled second face facilitate an intake or outlet (bi-directional airflow) area for air flow across the front side of the face plate into the plurality of holes.

In some embodiments, the angled portion of the top panel, the angled first face, and the angled second face facilitate an intake area for air flow across parallel switch devices assembled on a chassis. Furthermore, in some embodiments of the invention, the first face and the second face further includes a plurality of openings for corresponding I/O connectors. The I/O connectors of the first face and the second face are angled towards the front side of the faceplate. In an exemplary embodiment, the first face and the second face are angled towards the front panel at acute angles. In some embodiments, the faceplate further includes ejector levers on either side of the faceplate and a bottom panel attached to the front panel. The faceplate can is also removably attached to the switch device. In some embodiments, the faceplate is manufactured using extrusion. In other embodiments, the faceplate is manufactured using brass, computer numerical control (CNC), stamping, or any other available shaping metal plate process.

Although many of the examples herein are described with reference to a switch device, it should be understood that these are only examples, and that the present disclosure is not limited in this regard. Rather, any electronic component installed within a computer data center can be implemented within the disclosed convex feature.

Additional features and advantages of the disclosure will be set forth in the description which follows, and in part, will be obvious from the description, or can be learned by practice of the herein disclosed principles. The features and advantages of the disclosure can be realized and obtained by means of the instruments and combinations particularly pointed out in the appended claims. These and other features of the disclosure will become more fully apparent from the following description and appended claims, or can be learned by the practice of the principles set forth herein.

### BRIEF DESCRIPTION OF THE DRAWINGS

In order to describe the manner in which the above-recited disclosure, and its advantages and features, can be obtained, a more particular description of the principles briefly described above will be rendered by reference to specific examples illustrated in the appended drawings. These drawings depict only example aspects of the disclosure and are not therefore to be considered to be limiting of its scope. The principles are described and explained with additional specificity and detail through the use of the following drawings.

FIG. 1A shows a perspective view of a prior art computer device, exemplified without a cover to illustrate the internal components;

FIG. 1B shows a perspective view of a prior art computer device, exemplified with a cover;

FIG. 2 shows a front view of computing device implementing a convex faceplate according to one or more embodiments of the disclosure;

FIG. 3 shows a top view of the switch of FIG. 2, according to one or more embodiments of the disclosure;

FIG. 4 illustrates a plurality of switches assembled parallel to each other in a chassis, according to one or more embodiments of the disclosure;

FIG. 5 is a top view of the switch of FIG. 2 exemplifying the I/O connectors, according to one or more embodiments of the disclosure;

FIG. 6 is a top view of the switch of FIG. 2 exemplifying the I/O connectors and a chipset, according to one or more embodiments of the disclosure;

FIGS. 7A and 7B are diagrams exemplifying the improvement in signal strength corresponding with the proximity of the I/O connectors to the chipset.

### DETAILED DESCRIPTION

The present invention is described with reference to the attached figures, wherein like reference numerals are used throughout the figures to designate similar or equivalent elements. The figures are not drawn to scale, and they are provided merely to illustrate the instant invention. Several aspects of the invention are described below with reference to example applications for illustration. It should be understood that numerous specific details, relationships, and methods are set forth to provide a full understanding of the invention. One having ordinary skill in the relevant art, however, will readily recognize that the invention can be practiced without one or more of the specific details or with other methods. In other instances, well-known structures or operations are not shown in detail to avoid obscuring the invention. The present invention is not limited by the illustrated ordering of acts or events, as some acts may occur in different orders and/or concurrently with other acts or events. Furthermore, not all illustrated acts or events are required to implement a methodology in accordance with the present invention.

In general, one implementation of the subject matter disclosed herein is directed to a cooling assembly for cooling electronic devices within a rack server. In one or more implementations, the convex shaped faceplate offers an additional cross section to be utilized to increase airflow. The faceplate includes multiple vent holes for airflow. Thus, cooling, according to one or more implementations, occurs within the electronic device. The effectiveness of this technique can be enhanced by increasing the number of airflow vent holes and/or by increasing the angle of the faceplate to increase the surface area.

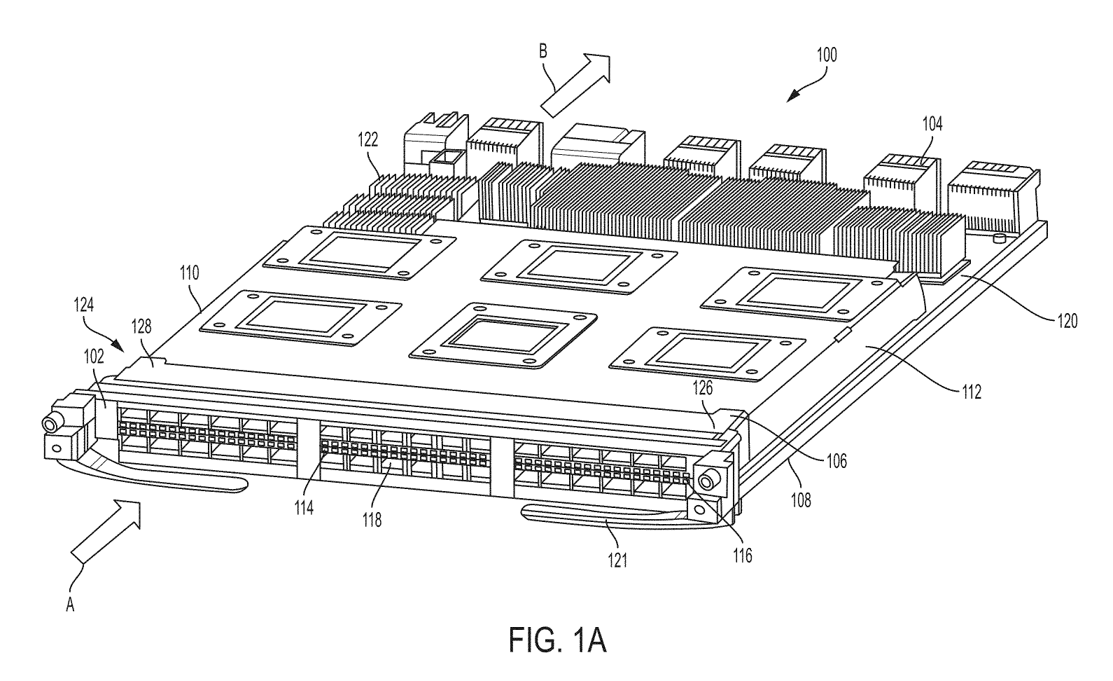

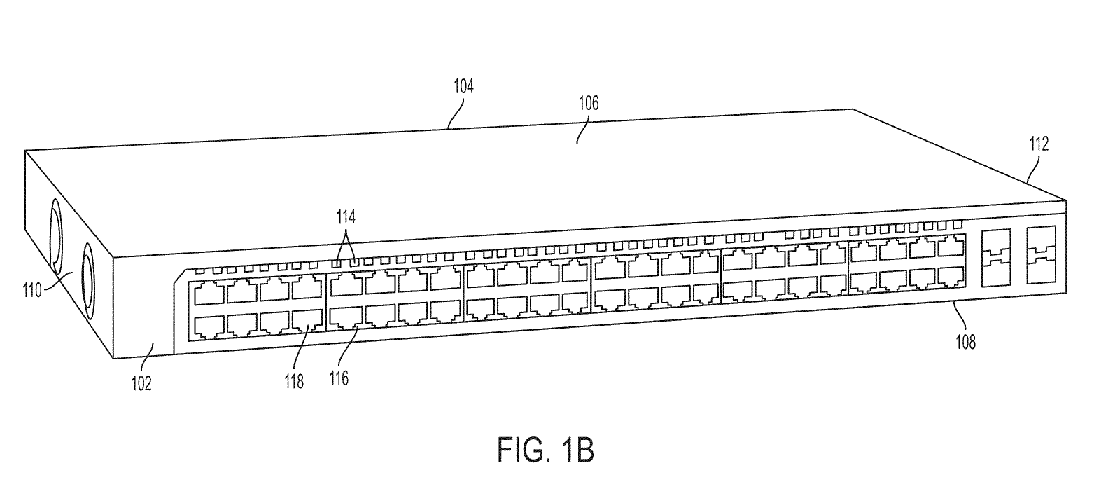

FIG. 1A illustrates a perspective view of a switch 100 of the prior art. The switch 100 may be one of a plurality of switches stacked in and supported by a chassis (not shown). The switch 100 includes a front 102, a back 104, a top 106, a bottom 108, a first side 110, and a second side 112. As shown in FIG. 1A, the switch 100 does not include a cover, as the chassis may act as a cover when the switch 100 is installed in the chassis. In another embodiment shown in FIG. 1B, the switch 100 includes a cover that surrounds any combination of the front 102, the back 104, the top 106, the bottom 108, the first side 110, and the second side 112.

Referring back to FIG. 1A, the front 102 of the switch 100 includes a plurality of openings 114 (e.g., vent holes) through which air used to cool the switch 100 flows. The front 102 also includes a plurality of openings 116 for corresponding I/O connectors 118, for example.

In some embodiments, the switch 100 includes any number of components including, for example, the I/O connectors 118, a plurality of heat generating electrical hardware components 120, a plurality of fans (not shown), a plurality of baffles (not shown), and other thermal management components (e.g., heat pipes). The I/O connectors 118, the plurality of heat generating electrical hardware components, the plurality of fans, the plurality of baffles, the other thermal management components, or a combination thereof may be supported by and/or attached to the bottom 108. The various components, or a combination thereof, can be attached to the bottom 108 by using an adhesive, screws, nut/bolt combinations, snaps, mated press fittings, other attachment devices, or a combination thereof. The switch 100 may include different, additional, or fewer components. For example, the switch 100 includes one or more rotatable levers 121 operable to lock the switch 100 in the chassis.

The I/O connectors 118 may be any number of I/O connectors 118 including, for example, RJ45 connectors or SFP connectors. The I/O connectors 118 may be used for input only, output only, or both input and output connections.

The plurality of heat generating electric hardware components 120 may include heat sinks 122 to aid in the transfer of heat from the plurality of heat generating electric hardware components 120 to the surrounding air. The plurality of heat generating electric hardware components 120 may include, for example, processors, circuits, transistors, memory devices, power supplies, transformers, chips, integrated circuits, or other electronics.

The plurality of fans pull or push (e.g., depending on the direction the plurality of fans are positioned within the switch 100) air into or out of the plurality of openings 114. In one embodiment, air is pulled into the switch 100 through the plurality of openings 114 in the direction of arrow A. At least a portion of the air is pushed out of the switch 100 at the back 104, as indicated by arrow B. In another embodiment, the flow of air is reversed, as air is pulled into the switch 100 at the back 104, and pushed out of the switch 100 through the plurality of openings 114 at the front 102.

The front 102 of the switch 100 may be formed by a faceplate 124. The faceplate 124 includes the plurality of openings 114 for airflow and the plurality of openings 116 for the I/O connectors 118. The faceplate 124 may be attached to the switch 100 in any number of ways. For example, the faceplate 124 may be attached to the switch 100 with a plurality of fasteners 126 at one or more flanges 128 of the faceplate 124. The plurality of fasteners 126 may include, for example, screw/tapped screw hole or nut/bolt combinations, but other connections such as snap or press fits or rivets may also be used.

The plurality of openings 114 are provided for thermal management purposes. Depending on the number of I/O connectors 118 and thus the size of the openings 116 provided for the I/O connectors 118 of the switch 100, there may be little space remaining for placement of the plurality of openings 114. Thus, there is a tradeoff between the number of plurality of openings 114 and the number of I/O connectors 118. For example, the more I/O connectors 118 present within the faceplate 124, the less space is available within the the faceplate 124 for vent holes. Conversely, you can provide more vent holes, as indicated in FIG. 1A, but lose space for the I/O connectors 118. This is kind of an important point we should be discussing. Additionally, the increased surface area allows for a greater spacing between components, which can also facilitate cooling.

For high power consumption switches or line cards, temperatures of one or more of the heat generating electrical hardware components during operation of the switch may be too great without sufficient airflow through the switch or line card to cool the heat generating electrical hardware components. The switch or line card may not operate properly and/or may shut down with such high temperatures. If the openings 114 are made too large and/or positioned too close together, the openings 114 may cause electro-magnetic interference and/or structural integrity issues. As indicated herein, the faceplate 124 is flat with respect to the front 102 of the switch 100.

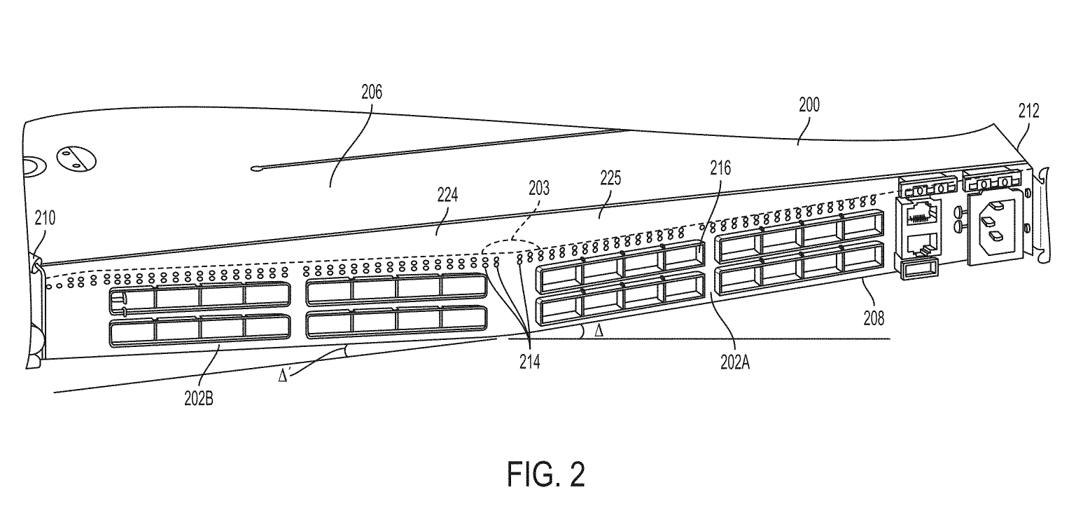

FIG. 2 illustrates a perspective view of one embodiment of a switch 200. The switch 200 includes a front 202 (202 is not shown in FIG. 2), a back (not shown), a top 206, a bottom 208, a first side 210, and a second side 212. The front 202 of the switch 200 includes a plurality of openings 214 (e.g., vent holes) through which air used to cool the switch 200 flows. The front 202 also includes a plurality of openings 216 for corresponding I/O connectors (not shown), for example. The front 202 of the switch 200 may be formed by a convex shaped faceplate 224. In the current embodiment, the convex faceplate 224 includes a triangular shape with an angle measuring less than 180°. In some embodiments, other shapes may be implemented. For example, although a triangular shape is indicated herein, a curved faceplate, a trapezoid faceplate or any other type of convex polygon can be implemented.

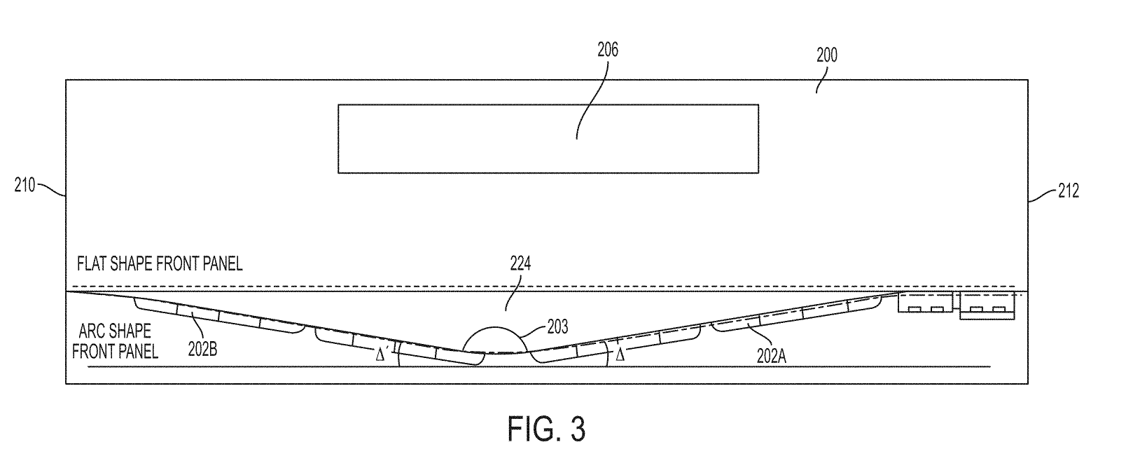

The convex faceplate 224 includes front side 202A angled back at an angle Δ. The convex faceplate 224 also includes front side 202B angled back at an angle Δ′. The faceplate 224 also includes a top panel 225 disposed on the top side of faceplate 224. The top panel 225 is attached to the front sides 202A and 202B to create an angled portion 203. The angled portion 203 is an obtuse angle, representing the convex shape of the faceplate 224. In various embodiments, the angled portion 203 of the top panel 225 and the front sides 202A and 202B facilitate an intake area for air flow between switch 200 and other parallel line cards assembled on a chassis (discussed below in greater detail). In some embodiments, the faceplate 224 is removably attached to the switch 200, for example, using suitable screws or nuts and bolts. FIG. 3 shows a top view of one embodiment of the switch 200.

In various embodiments, the faceplate 224 may be manufactured using existing manufacturing processes, such as extrusion. It should be understood that other manufacturing methods can be implemented herein. For example, the face plate material can be made from plastic material. In a general sense, extrusion is a generally known manufacturing process in which a material is pushed or drawn through a die of a desired cross-section. Extrusion may be continuous (e.g., producing long material of intricate shape) or semi-continuous (e.g., producing many pieces, each of intricate shape). The extrusion process can be done with hot or cold material. In various embodiments, the material used for faceplate 224 may comprise aluminum. Note that any suitable manufacturing material can be used within the broad scope of the embodiments, for example, any metallic, plastic or even wood material can be implemented herein. The plurality of openings 214 can be formed using a CNC milling machine or using any other process suitable for creating such openings.

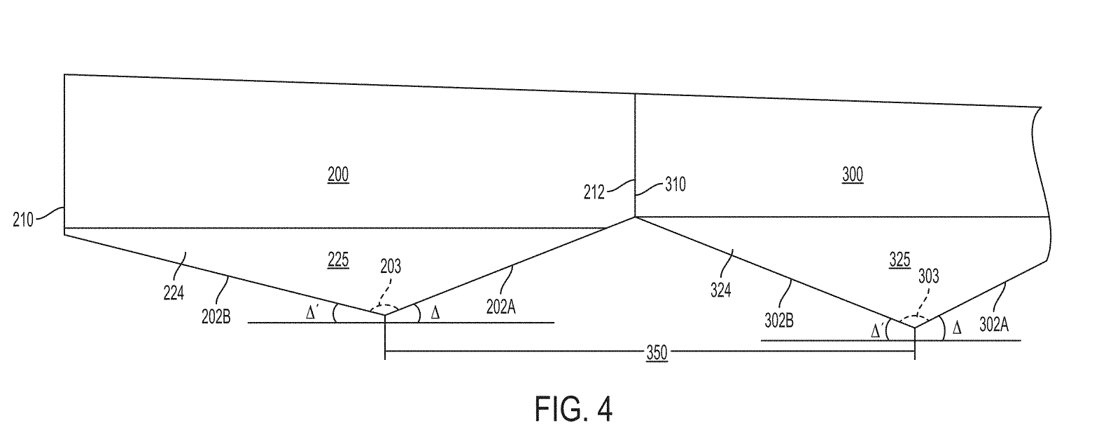

FIG. 4 illustrates a plurality of switches assembled parallel to each other in a chassis. The switch 200 includes a first side 210 and a second side 212. The switch 200 also includes a convex faceplate 224. The convex faceplate 224 includes front side 202A angled back at an angle Δ. The convex faceplate 224 also includes front side 202B angled back at an angle Δ′. The faceplate 224 also includes a top panel 225 disposed on the top side of faceplate 224. The top panel 225 is attached to the front sides 202A and 202B to create an angled portion 203. The switch 300 includes a first side 310 that abuts the second side 212 of the switch 200. (The second side of the switch 300 is not visible in FIG. 4.) The switch 300 can also include a convex faceplate 324. The convex faceplate 324 includes front side 302A angled back at an angle Δ. The convex faceplate 324 also includes front side 302B angled back at an angle Δ′. The faceplate 324 also includes a top panel 325 disposed on the top side of faceplate 324. The top panel 325 is attached to the front sides 302A and 302B to create an angled portion 303.

In various embodiments, a channel 350 for air flow is disposed between the faceplate 224 of the switch 200 and the faceplate 324 of the switch 300. In particular embodiments, angled portions 203 and 303 of the top panels 225 and 325 facilitate an intake area of the channel 350. The channel 350 increases the airflow along the front sides 202A and 302B. In some embodiments, the first side 210 of switch 200 may also abut another switch creating another channel for air flow along the front side 202B. Similarly, the second side of switch 300 (not shown) may also abut another switch creating another channel for air flow along the front side 302A.

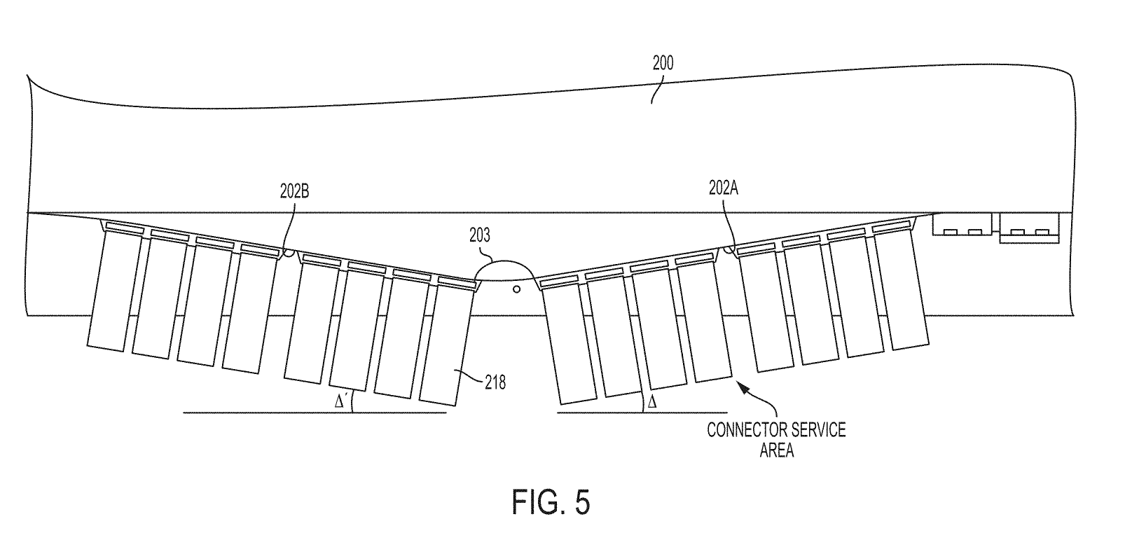

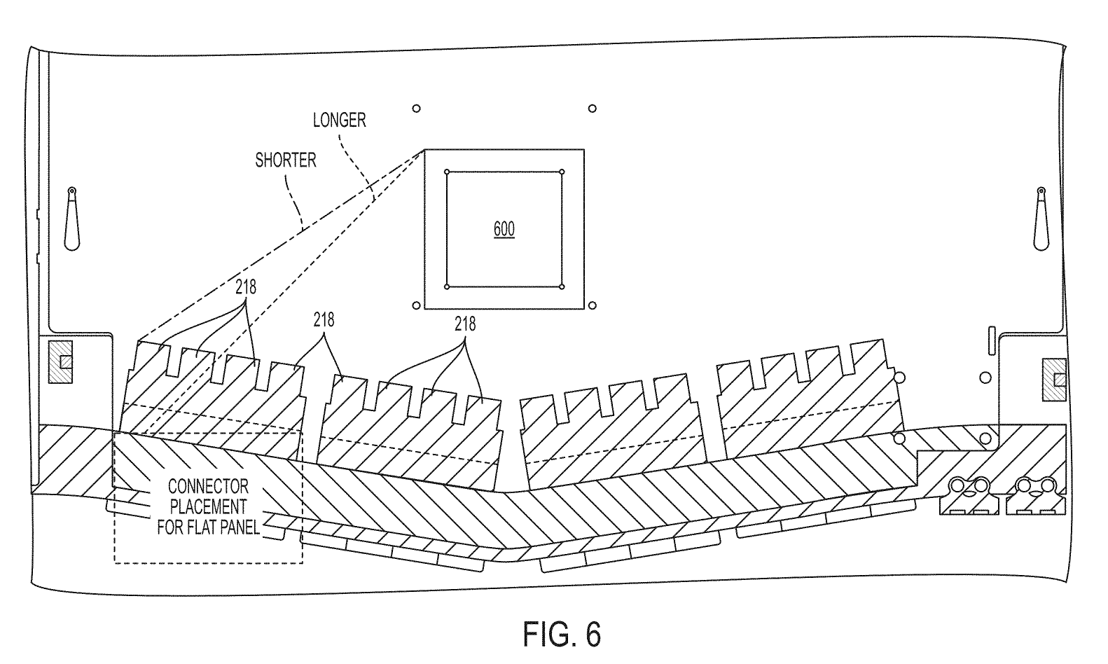

FIG. 5 is a top view of one embodiment of the switch 200 exemplifying the I/O connectors 218. The I/O connectors 218 may be any number of I/O connectors 218 including, for example, RJ45 connectors or SFP connectors. The I/O connectors 218 may be used for input only, output only, or both input and output connections. The I/O connectors 218 are positioned within front sides 202B and 202A. Thus, the I/O connectors 218 are also angled back at an angle Δ′ and Δ. The positioning of the I/O connectors 218 along front sides 202B and 202A, at an angle Δ′ and Δ, creates additional space to include more I/O connectors 218. Furthermore, the positioning of the I/O connectors 218 along front sides 202B and 202A, at an angle Δ′ and Δ, assists in improving signal integrity of the connector. This is discussed in greater detail below with respect to FIG. 6.

FIG. 6 is a top view of one embodiment of the switch 200 exemplifying the I/O connectors and a chipset 600. The switch 200 includes a first chipset 600 which includes switches (not shown) and a chip (not shown). As shown, chipset 600 is arranged to support ports associated I/O connectors 218. The I/O connectors 218 are also angled back at an angle Δ′ and Δ. Thus, the distance between the I/O connectors 218 and the chipset 600 is reduced. Because the I/O connectors 218 are placed physically closer to the chipset 600, the signal integrity of the connector can be improved.

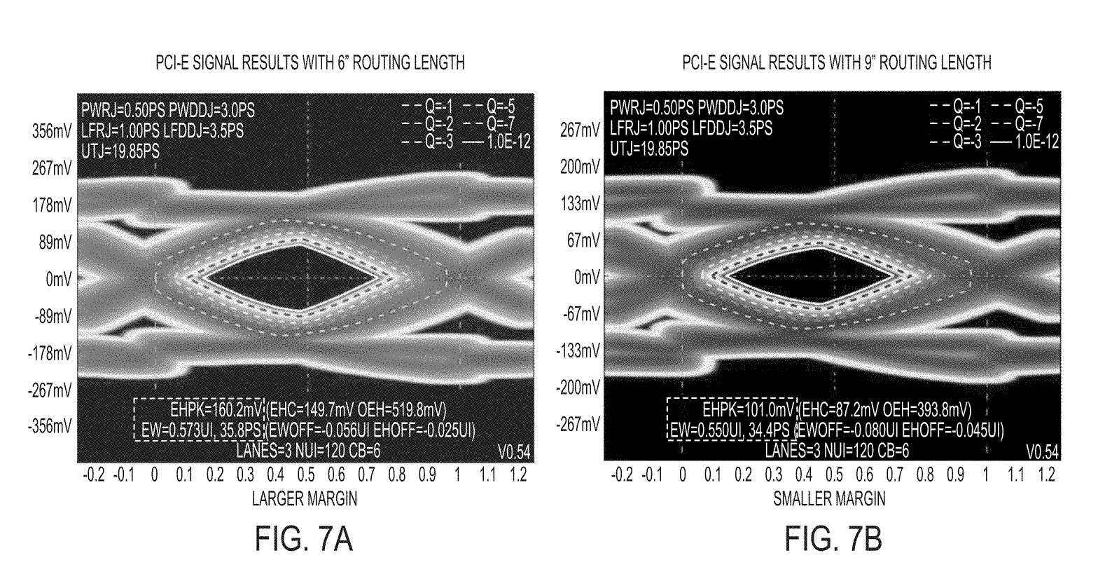

FIGS. 7A and 7B are diagrams exemplifying the improvement in signal strength corresponding with the proximity of the I/O connectors to the chipset. FIGS. 7A and 7B illustrates an exemplary 6 and 9 inches of routing length, respectively. FIG. 7B exemplifies the PCI-E signal results where the routing length to the chip set is 9 inches. When the routing length is 9 inches, the ehpk measures to be 101.0 mV. Furthermore, when the routing length is 9 inches, the ew=0.550 UI, and 34.4 ps. The signal strength improves when the routing length is shortened to 6 inches. FIG. 7A exemplifies the PCI-E signal results where the routing length to the chipset is 6 inches. For example, the ehpk measures to 160.2 mV. Furthermore, the ew=0.573 UI, and 35.8 ps.

While various embodiments of the present invention have been described above, it should be understood that they have been presented by way of example only, and not limitation. Numerous changes to the disclosed embodiments can be made in accordance with this disclosure without departing from the spirit or scope of the invention. Thus, the breadth and scope of the present invention should not be limited by any of the above described embodiments. Rather, the scope of the invention should be defined in accordance with the following claims and their equivalents.

Although the invention has been illustrated and described with respect to one or more implementations, equivalent alterations and modifications will occur to others skilled in the art upon the reading and understanding of this specification and the annexed drawings. In addition, while a particular feature of the invention may have been disclosed with respect to only one of several implementations, such feature may be combined with one or more other features of the other implementations as may be desired and advantageous for any given or particular application.

The terminology used herein is for the purpose of describing particular embodiments only and is not intended to limit the invention. As used herein, the singular forms “a”, “an”, and “the” are intended to include the plural forms as well, unless the context clearly indicates otherwise. Furthermore, to the extent that the terms “including”, “includes”, “having”, “has”, “with”, or variants thereof are used in either the detailed description and/or the claims, such terms are intended to be inclusive in a manner similar to the term “comprising.”

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art, and will not be interpreted in an idealized or overly formal sense unless expressly so defined herein.

What is claimed is:

1. A faceplate of an apparatus, comprising:
a top panel including a portion angled towards a front side of the faceplate, the angled portion comprising an obtuse angle; and
a front panel disposed on the front side of the faceplate, the front panel comprising a first face angled towards the front side of the faceplate and a second face angled towards the front side of the faceplate, the first face and the second face having a plurality of holes, wherein the angled portion of the top panel, the angled first face, and the angled second face facilitate an intake/outlet area for air flow across the front side of the front side of the face plate.

2. The faceplate of claim 1, wherein the angled portion of the top panel, the angled first face and the angled second face facilitate an intake/outlet area for air flow across parallel apparatuses assembled on a chassis.

3. The faceplate of claim 1, wherein the first face and the second face further comprising a plurality of openings for corresponding I/O connectors.

4. The faceplate of claim 3, wherein the I/O connectors of the first face and the second face are angled towards the front side of the faceplate.

5. The faceplate of claim 1, wherein the first face and the second face are angled towards the front panel at acute angles.

6. The faceplate of claim 1, wherein the faceplate further comprises:
ejector levers on either side of the faceplate; and
a bottom panel attached to the front panel.

7. The faceplate of claim 1, wherein the faceplate is removably attached to the switch.

8. The faceplate of claim 1, wherein the faceplate is manufactured using extrusion.

9. An apparatus comprising:
a switch;
a fan disposed towards a back side of the apparatus; and
a plurality of line cards removably attached and electrically connected to the switch, wherein the line cards are disposed parallel to each other, wherein each line card includes a faceplate comprising:
a top panel including a portion angled towards a front side of the faceplate, the angled portion comprising an obtuse angle; and
a front panel disposed on the front side of the faceplate, the front panel comprising a first face angled towards the front side of the faceplate and a second face angled towards the front side of the faceplate, the first face and the second face having a plurality of holes, wherein the angled portion of the top panel, the angled first face, and the angled second face facilitate an intake/outlet area for air flow across the front side of the face plate.

10. The apparatus of claim 9, wherein a channel for air flow is disposed between the first face of the faceplate of any one line card, and the second face of the faceplate of an adjacent line card.

11. The apparatus of claim 10, wherein the fan is disposed behind the line cards towards a back of the apparatus, wherein when the fan operates, air is pulled in through the channel from the front of the faceplates and is forced over one or more heat generating components on each line card.

12. The apparatus of claim 9, wherein the first face and the second face further comprising a plurality of openings for corresponding I/O connectors.

13. The apparatus of claim 12, wherein the I/O connectors of the first face and the second face are angled towards the front side of the faceplate.

14. The apparatus of claim 9, wherein the first face and the second face are angled towards the front panel at acute angles.

15. The apparatus of claim 9, wherein the faceplate further comprises:
ejector levers on either side of the faceplate; and
a bottom panel attached to the front panel.

16. The apparatus of claim 9, wherein the faceplate is manufactured using at least one of extrusion, rolling, brass, and CNC.

17. A chassis of an apparatus, comprising:
a front end; and
a rear end, wherein at least one of the ends of the chassis comprises a convex shape.

18. The chassis of claim 17, wherein the at least one of the ends of the chassis comprises plurality of openings.

19. The chassis of claim 18, wherein the plurality of openings comprises openings for airflow, wherein each of the openings are equal distance to a chipset located at the at least one of the ends of the chassis.

20. The chassis of claim 18, wherein the plurality of openings comprises openings for I/O connectors.
